(19) United States
(12) Patent Application Publication
(10) Pub. No.: US 2012/0326324 A1
(43) Pub. Date: Dec. 27, 2012

(54) INTEGRATED CIRCUIT PACKAGING SYSTEM WITH PACKAGE STACKING AND METHOD OF MANUFACTURE THEREOF

(76) Inventors: HyungMin Lee, Bucheon-si (KR); HeeJo Chi, Ichon-si (KR); YeongIm Park, Yongin-city (KR)

(21) Appl. No.: 13/166,679

(22) Filed: Jun. 22, 2011

(51) Int. Cl. H01L 23/48; H01L 21/56

(52) U.S. Cl. 257/774; 438/124; 257/E23.011; 257/E21.502

(57) ABSTRACT

A method of manufacture of an integrated circuit packaging system includes: providing a base substrate; mounting an organic chip assembly on the base substrate, the organic chip assembly includes providing an assembly integrated circuit embedded in an organic cover, the organic cover having a through via, and the organic chip assembly having a vertical assembly side; forming a molded underfill encapsulating the vertical assembly side, and between the organic chip assembly and the base substrate; and removing a portion of the organic chip assembly and the molded underfill for forming a planarized assembly surface.

### TECHNICAL FIELD

The present invention relates generally to an integrated circuit packaging system, and more particularly to a package stacking method.

### BACKGROUND ART

The integrated circuit package is the building block used in a high performance electronic system to provide applications for usage in products such as automotive vehicles, pocket personal computers, cell phone, intelligent portable military devices, aeronautical spacecraft payloads, and a vast line of other similar products that require small compact electronics supporting many complex functions.

A small product, such as a cell phone, can contain many integrated circuit packages, each having different sizes and shapes. Each of the integrated circuit packages within the cell phone can contain large amounts of complex circuitry. The circuitry within each of the integrated circuit packages work and communicate with other circuitry of other integrated circuit packages using electrical connections.

Products must compete in world markets and attract many consumers or buyers in order to be successful. It is very important for products to continue to improve in features, performance, and reliability while reducing product costs, product size, and to be available quickly for purchase by the consumers or buyers.

The amount of circuitry and the amount of electrical connections inside a product are key to improving the features, performance, and reliability of any product. Furthermore, the ways the circuitry and electrical connections are implemented can determine the packaging size, packaging methods, and the individual packaging designs.

Attempts have failed to provide a complete solution addressing simplified manufacturing processing, smaller dimensions, lower costs due to design flexibility, increased functionality, leveragability, and increased IO connectivity capabilities.

Thus, a need still remains for an integrated circuit system improved yield, low profile, and improved reliability. In view of the ever-increasing commercial competitive pressures, along with growing consumer expectations and the diminishing opportunities for meaningful product differentiation in the marketplace, it is increasingly critical that answers be found to these problems. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: providing a base substrate; mounting an organic chip assembly on the base substrate, the organic chip assembly includes providing an assembly integrated circuit embedded in an organic cover, the organic cover having a through via, and the organic chip assembly having a vertical assembly side; forming a molded underfill encapsulating the vertical assembly side, and between the organic chip assembly and the base substrate; and removing a portion of the organic chip assembly and the molded underfill for forming a planarized assembly surface.

The present invention provides an integrated circuit packaging system, including: a base substrate; an organic chip assembly mounted on the base substrate and having a planarized assembly surface, the planarized assembly surface includes an inactive side of an assembly integrated circuit coplanar to an organic cover with a through via, the organic chip assembly having a vertical assembly side; and a molded underfill encapsulating the vertical assembly side, and between the organic chip assembly and the base substrate.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit packaging system taken along a line 1-1 of FIG. 2 in a first embodiment of the present invention.

FIG. 2 is a top view of the integrated circuit packaging system.

FIG. 3 is the cross-sectional view of the organic chip assembly in a wafer sawing and wafer expansion phase.

FIG. 4 is the structure of FIG. 3 in an organic material application phase.

FIG. 5 is the structure of FIG. 4 in an organic material sawing phase.

FIG. 6 is the structure of FIG. 5 in an organic cavity creation phase.

FIG. 7 is the structure of FIG. 6 in a via conductor forming phase.

FIG. 8 is the structure of FIG. 7 in an assembly connector application phase.

FIG. 9 is the structure of FIG. 4 in a second organic cavity creation phase in a second embodiment of the present invention.

FIG. 10 is the structure of FIG. 9 in a via conductor forming phase.

FIG. 11 is the structure of FIG. 10 in an assembly connector application phase.

FIG. 12 is the structure of FIG. 11 in an organic material sawing phase.

FIG. 13 is a bottom view of the organic chip assembly of FIG. 12.

FIG. 14 is the organic chip assembly in a base substrate attach phase.

FIG. 15 is the structure of FIG. 14 in a molded underfill application phase.

FIG. 16 is the structure of FIG. 15 in an assembly top side thinning phase.

FIG. 17 is the structure of FIG. 16 in a stacked package attachment phase.

FIG. 18 is a cross-sectional view of an integrated circuit packaging system exemplified by the top view along line 1-1 of FIG. 2 in a third embodiment of the present invention.

FIG. 19 is a cross-sectional view of an integrated circuit packaging system exemplified by the top view along line 1-1 of FIG. 2 in a fourth embodiment of the present invention.

FIG. 20 is a cross-sectional view of an integrated circuit packaging system exemplified by the top view along line 1-1 of FIG. 2 in a fifth embodiment of the present invention.

FIG. 21 is a cross-sectional view of an integrated circuit packaging system exemplified by the top view along line 1-1 of FIG. 2 in a sixth embodiment of the present invention.

FIG. 22 is a flow chart of a method of manufacture of the integrated circuit packaging system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown greatly exaggerated in the drawing FIGs. Similarly, although the views in the drawings shown for ease of description and generally show similar orientations, this depiction in the FIGs. is arbitrary for the most part. Generally, the invention can be operated in any orientation.

Where multiple embodiments are disclosed and described having some features in common, for clarity and ease of illustration, description, and comprehension thereof, similar and like features one to another will ordinarily be described with similar reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane of the active surface of the integrated circuit, regardless of its orientation. The term “vertical” refers to a direction perpendicular to the horizontal as just defined. The term “non-horizontal” refers to any angle between horizontal including vertical as previously defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” means that there is direct contact between elements.

The term “active side” refers to a side of a die, a module, a package, or an electronic structure having active circuitry fabricated thereon or having elements for connection to the active circuitry within the die, the module, the package, or the electronic structure. The term “processing” as used herein includes deposition of material or photoresist, patterning, exposure, development, etching, cleaning, and/or removal of the material or photoresist as required in forming a described structure.

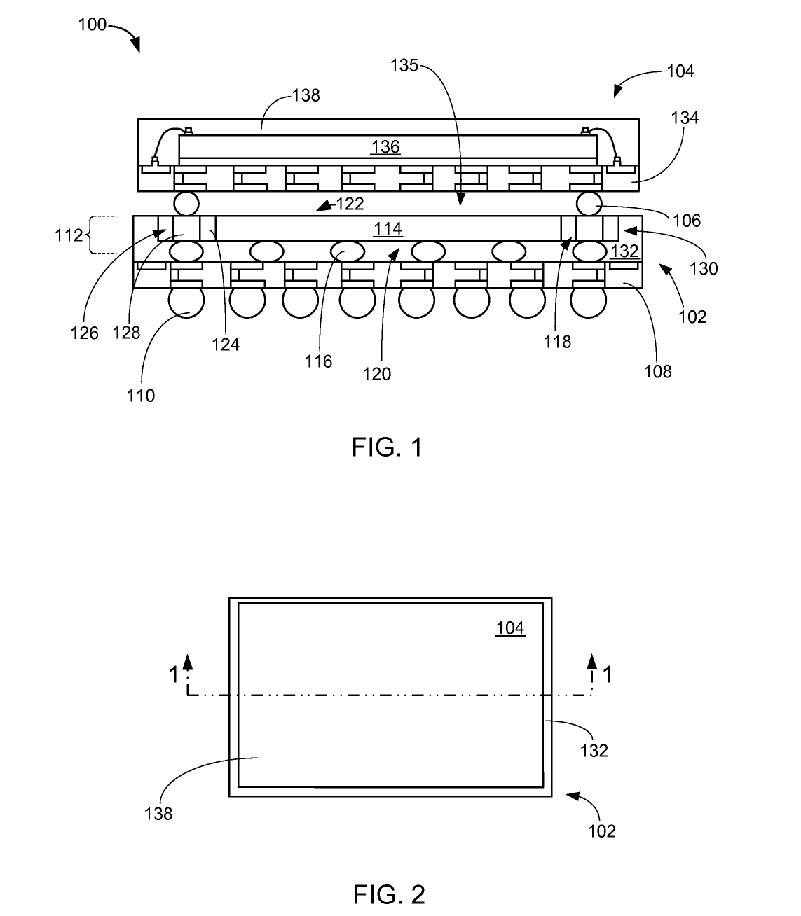

Referring now to FIG. 1, therein is shown a cross-sectional view of an integrated circuit packaging system 100 taken along a line 1-1 of FIG. 2 in a first embodiment of the present invention. The integrated circuit packaging system 100 can include an organic base package 102 connected to a stack package 104 using a package interconnect 106, such as solder, solder balls, solder dots, solder bumps, or other conductive structures.

The organic base package 102 is defined as a base package, with organic structures, for providing structural support and environmental protection for an integrated circuit. The organic base package 102 can include a base substrate 108, a system interconnect 110, and an organic chip assembly 112.

The base substrate 108 is defined as a base structure that provides support and connectivity for other components and devices. The base substrate 108 can include conductive layers and conductive traces embedded therein.

The system interconnect 110 is defined as an electrical connector providing direct electrical and mechanical to the next system level (not shown). As an example, the system interconnect 110 can be solder balls, solder pillars, or conductive bumps. The system interconnect 110 can be used to attach the organic base package 102 to the next level system.

The organic chip assembly 112 is defined as an integrated circuit structure including an assembly integrated circuit 114, an assembly connector 116, and an organic cover 124 with a through via 118. The assembly integrated circuit 114 is defined as an integrated circuit of the organic chip assembly 112. The assembly integrated circuit 114 can have an active side 120 with active circuitry fabricated thereon and an inactive side 122 opposite to the active side 120.

The assembly connector 116 is defined as conductive structure for mounting the organic chip assembly 112 to another structure. As an example, the assembly connector 116 can be solder balls, solder pillars, or conductive bumps. The assembly connector 116 can be used to mount the organic chip assembly 112 to the base substrate 108.

The organic cover 124 is defined as an organic polymer for enclosing the vertical sidewalls of the assembly integrated circuit 114. The organic cover 124 can surround the vertical sidewalls of the assembly integrated circuit 114 but not cover the active side 120 and the inactive side 122 of the assembly integrated circuit 114. The organic cover 124 can provide structural support during chip thinning and back-grinding of the assembly integrated circuit 114. The organic cover 124 can be formed from epoxy molding compound (EMC), moldable underfill (MUF), Polyimide (PI), Benzocyclobutene (BCB), or other organic resin materials.

The organic cover 124 can include a hole 126 formed completely through the organic cover 124. The hole 126 can be formed away from the assembly integrated circuit 114 such that the vertical sides of the assembly integrated circuit 114 are not exposed from the organic cover 124. The hole 126 can be filled with an via conductor 128 for forming the through via 118.

The via conductor 128 is defined as a conductive material within the hole 126 for providing an electrical pathway. For example, the conductive substance of the via conductor 128 can include solder, aluminum, copper, silver, gold, or other conductive materials.

The via conductor 128 within the hole 126 can form the through via 118. The through via 118 can provide a vertical electrical connection passing completely through the organic cover 124.

The assembly connector 116 can be mounted on the via conductor 128 of the through via 118 and mounted to the active side 120 of the assembly integrated circuit 114. The size of the assembly connector 116 can be proportional to the width of the opening of the hole 126. The height of the assembly connector 116 and the organic cover 124 with the through via 118 allows for smaller solder balls to be used in the integrated circuit packaging system 100.

The assembly connector 116 can attach the organic chip assembly 112 to the base substrate 108. The organic chip assembly 112 can also include a vertical assembly side 130, which is defined as a non-horizontal side of the organic chip assembly 112 and perpendicular to the inactive side 122 of the assembly integrated circuit 114.

The organic base package 102 can include a molded underfill 132, which is defined as curable liquid underfill material for sealing integrated circuits and semiconductor structures. For example, the molded underfill 132 can be a material that is liquid at room temperature and curable by heat to form a solid.

The molded underfill 132 can provide mechanical and environmental protection for the organic base package 102. The molded underfill 132 can encapsulate the active side 120 of the assembly integrated circuit 114, the vertical assembly side 130, the assembly connector 116, and between the organic chip assembly 112 and the base substrate 108 for providing mechanical and environmental protection.

The organic base package 102 can include a planarized assembly surface 135. The planarized assembly surface 135 is defined as a planarized surface of the organic chip assembly 112 and the molded underfill 132 that faces away from the base substrate 108. The planarized assembly surface 135 can include the inactive side 122 of the assembly integrated circuit 114 and surfaces of the molded underfill 132, the organic cover 124, and the via conductor 128 that face away from the base substrate 108.

The molded underfill 132 and the organic chip assembly 112 can be thinned or back-grinded to form the planarized assembly surface 135. The planarized assembly surface 135 can be thinned or back-grinded by a number of processes including chemical mechanical planarization (CMP), wheel grinding, or sawing.

The integrated circuit packaging system 100 can include the stack package 104, which is defined as an integrated circuit package for mounting above a base package. The stack package 104 can include a stack substrate 134, a stack semiconductor device 136, and a stack encapsulation 138.

The package interconnect 106 can be mounted on the through via 118, and the stack package 104 can be mounted on the package interconnect 106 and mounted over the inactive side 122 of the assembly integrated circuit 114. The stack semiconductor device 136 is defined as an integrated circuit of the stack package 104.

For illustrative purposes, the stack semiconductor device 136 can include a wire-bond device or flip chip. The stack encapsulation 138 is defined as an encapsulation for the stack package 104. The stack encapsulation 138 can include an epoxy molding compound (EMC), polymide compound, or a wire-in-film (WIF).

It has been discovered that the organic cover 124 with the through via 118 of the organic chip assembly 112 provides the integrated circuit packaging system 100 with a finer pitch interconnect over prior art package-on-package (PoP) technology. The organic cover 124 with the through via 118 provides a conductive mounting structure for smaller solder balls and interconnects between packages. The smaller solder balls and interconnects provide for finer pitch interconnections between the stack package 104 and the organic base package 102 than a larger solder ball for connecting the stack package 104 with a convention base package.

The width of the hole 126 and the via conductor 128 of the through via 118 enables the conductive material mounted thereon to be smaller in size resulting in increased IO density between the stack package 104 and the organic base package 102. The smaller size of the package interconnect 106 and the assembly connector 116 also prevents solder ball collapse over larger conventional solder balls during reflow.

Further, it has been discovered that the stacking configuration of the organic base package 102 and the stack package 104 reduces the impact of the coefficient of thermal expansion and thus prevents damage to the integrated circuit packaging system 100. The placement of the through via 118, the molded underfill 132, the assembly connector 116, the package interconnect 106, and the system interconnect 110 provide for a similar coefficient of thermal expansion at each package level of the integrated circuit packaging system 100, preventing interconnect fractures between the organic base package 102 and the stack package 104.

Further, it has been discovered that the organic cover 124 enclosing the vertical sidewalls of the assembly integrated circuit 114 and the base substrate 108 provide for structural support for the assembly integrated circuit 114 during thinning, back-grinding, or chemical mechanical planarization. The organic cover 124 and the base substrate 108 provide a supporting structure for the organic chip assembly 112 and the increased support prevents the assembly integrated circuit 114 from breaking or fracturing during die thinning

Further, it has been discovered that the organic cover 124 with the through via 118 on the peripheral of the assembly integrated circuit 114 provides for interchangeable packages to be mounted to the organic base package 102. The configuration of the organic base package 102 makes multiple function integration possible. The organic base package 102 with the molded underfill 132 sealing the organic chip assembly 112 to the base substrate 108 provides for lower production line utilization by removing the need of additional steps, adhesives, separate underfill, and molds.

Referring now to FIG. 2, therein is shown a top view of the integrated circuit packaging system 100. The integrated circuit packaging system 100 can include the stack encapsulation 138 of the stack package 104 and the molded underfill 132 of the organic base package 102. The molded underfill 132 can be seen below the stack package 104.

For purposes of illustration, the integrated circuit packaging system 100 is shown with the stack package 104 having a footprint area smaller than the footprint area of the organic base package 102, although it is understood that the integrated circuit packaging system 100 can have a different configuration. For example, the relative footprint of the stack package 104 can be the same size or larger than the footprint of the organic base package 102.

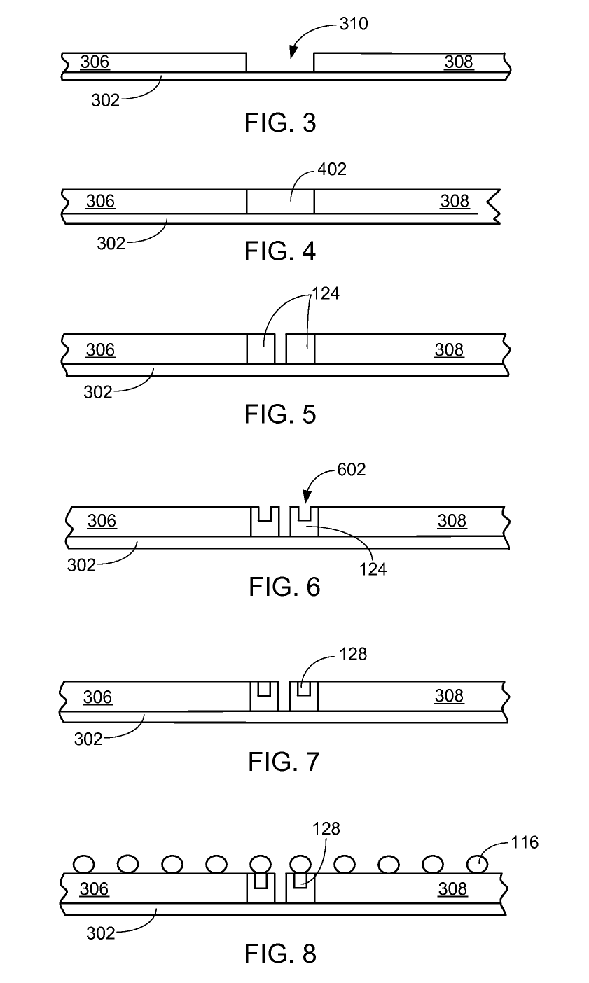

Referring now to FIG. 3, therein is shown the cross-sectional view of the organic chip assembly 112 in a wafer sawing and wafer expansion phase. A wafer carrier 302, which is defined as a structure for holding a wafer for various processing step, is shown with a wafer that has been singulated into a first integrated circuit 306 and a second integrated circuit 308.

The first integrated circuit 306 and the second integrated circuit 308 can be similar to the assembly integrated circuit 114 of FIG. 1. The circuitry within the first integrated circuit 306 can be the identical or different from the circuitry in the second integrated circuit 308.

A bonding agent, such as a wax, solvable glue, thermally releasable adhesive tape, or other appropriate attaching material, can be used for attaching the first integrated circuit 306 and the second integrated circuit 308 to the wafer carrier 302. A wafer can be attached to the wafer carrier 302 and singulated for forming the first integrated circuit 306 and the second integrated circuit 308.

The first integrated circuit 306 and the second integrated circuit 308 can be evenly spaced from each other, forming a gap 310 between the first integrated circuit 306 and the second integrated circuit 308. The wafer carrier 302 can include an expansion ring for separating the first integrated circuit 306 and the second integrated circuit 308 of a specific distance after singulation.

Further for example, a robotic “pick and place” method can be used on the first integrated circuit 306 and the second integrated circuit 308 to evenly space the chips from each other on a separate carrier.

Referring now to FIG. 4, therein is shown the structure of FIG. 3 in an organic material application phase. The phase depicts the first integrated circuit 306, the second integrated circuit 308, and the wafer carrier 302. An organic filling 402 is defined as a carbon material for filling between vertical sidewalls of integrated circuits.

The organic filling 402 is applied in the gap 310 of FIG. 3 between the first integrated circuit 306 and the second integrated circuit 308 and along the periphery of the first integrated circuit 306 and the second integrated circuit 308. The organic filling 402 can be applied to have the same thickness as the thickness of the first integrated circuit 306. The organic filling 402 can adhere to the vertical sides of the first integrated circuit 306 and the second integrated circuit 308.

Referring now to FIG. 5, therein is shown the structure of FIG. 4 in an organic material sawing phase. The phase depicts the first integrated circuit 306, the second integrated circuit 308, and the wafer carrier 302.

The organic filling 402 can be singulated at a midpoint of the organic filling 402 between the first integrated circuit 306 and the second integrated circuit 308 to form the organic cover 124. The organic cover 124 is attached to the first integrated circuit 306 and another of the organic cover 124 is attached to the second integrated circuit 308 after singulation. The organic filling 402 can be singulated by a number of processes, such as a sawing or laser scribing.

Referring now to FIG. 6, therein is shown the structure of FIG. 5 in an organic cavity 602 creation phase. The phase depicts the first integrated circuit 306, the second integrated circuit 308, and the wafer carrier 302.

The organic cavity 602 is defined as an indention or cavity formed in the organic cover 124. The indention or cavity within the organic cover 124 can be formed by drilling or etching. The depth of the organic cavity 602 can depend on the final thickness of the completed semiconductor chip but the organic cavity 602 does not completely pass through the organic cover 124.

Referring now to FIG. 7, therein is shown the structure of FIG. 6 in a via conductor forming phase. The phase depicts the first integrated circuit 306, the second integrated circuit 308, and the wafer carrier 302.

The via conductor 128 can be formed in the organic cavity 602 by employing a number of different processes. For example, the via conductor 128 can be formed with a filling process, an injecting process, or a dispensing process.

Referring now to FIG. 8, therein is shown the structure of FIG. 7 in the assembly connector 116 application phase. The phase depicts the first integrated circuit 306, the second integrated circuit 308, and the wafer carrier 302. The assembly connector 116 can be applied to the via conductor 128 and the active side of the first integrated circuit 306 and the second integrated circuit 308.

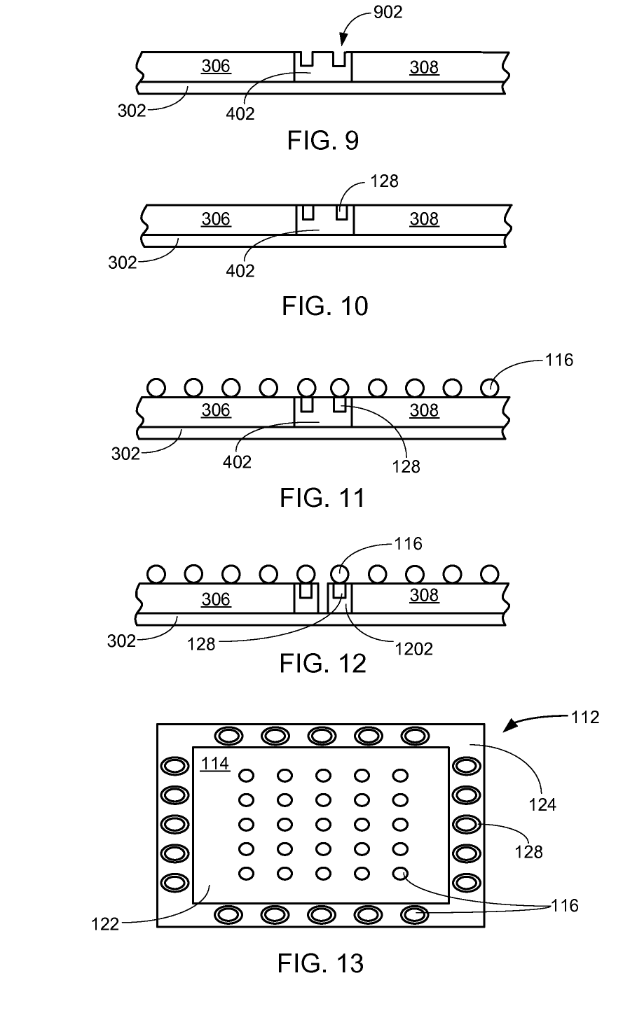

Referring now to FIG. 9, therein is shown the structure of FIG. 4 in a second organic cavity creation phase in a second embodiment of the present invention. The phase depicts the first integrated circuit 306, the second integrated circuit 308, the wafer carrier 302, and the organic filling 402.

A second organic cavity 902 is defined as an indention or cavity formed in the organic filling 402 by drilling or etching. The deepness of the second organic cavity 902 can depend on the final thickness of the completed semiconductor chip but the second organic cavity 902 does not completely pass through the organic filling 402. The second organic cavity 902 creation phase of the second embodiment differs from the phase shown in FIG. 5 because the organic filling 402 has not been singulated to form the organic cover 124 of FIG. 5.

Referring now to FIG. 10, therein is shown the structure of FIG. 9 in a via conductor forming phase. The phase depicts the first integrated circuit 306, the second integrated circuit 308, the wafer carrier 302, and the organic filling 402.

The via conductor 128 can fill the second organic cavity 902 of FIG. 9. The via conductor 128 can include solder, aluminum, copper, silver, gold, or other conductive materials. The via conductor 128 can be formed in the second organic cavity 902 by employing a number of different processes. For example, the via conductor 128 can be formed with a filling process, an injecting process, or a dispensing process.

Referring now to FIG. 11, therein is shown the structure of FIG. 10 in an assembly connector 116 application phase. The phase depicts the first integrated circuit 306, the second integrated circuit 308, the wafer carrier 302, and the organic filling 402. The assembly connector 116 can be mounted to the via conductor 128 and the active side of the first integrated circuit 306 and the second integrated circuit 308.

Referring now to FIG. 12, therein is shown the structure of FIG. 11 in an organic material sawing phase. The phase depicts the first integrated circuit 306, the second integrated circuit 308, and the wafer carrier 302.

The organic filling 402 of FIG. 11 is singulated at a midpoint between the first integrated circuit 306 and the second integrated circuit 308 to form a second organic cover 1202. The second organic cover 1202 can include the via conductor 128 and the assembly connector 116. The organic filling 402 can be singulated by a number of processes, such as a sawing or laser scribing.

Referring now to FIG. 13, therein is shown a bottom view of the organic chip assembly 112. The organic chip assembly 112 can include the inactive side 122 of the assembly integrated circuit 114, the organic cover 124, the via conductor 128, and the assembly connector 116.

For illustrative purposes, the assembly connector 116 on the inactive side 122 of the assembly integrated circuit 114 can be arranged in a five by five rectangular array although it is understood that the assembly connector 116 can be arranged in other configurations. For example, the assembly connector 116 can be arranged in a square array and with more or less rows and columns of the assembly connector 116.

The via conductor 128 and the assembly connector 116 mounted thereon can be arranged along a periphery of the assembly integrated circuit 114. For illustrative purposes, the organic chip assembly 112 can include five of the via conductor 128 on each of the peripheries of the organic chip assembly 112. The via conductor 128 on one periphery of the assembly integrated circuit 114 can be coplanar with another of the via conductor 128 on the opposite periphery of the assembly integrated circuit 114.

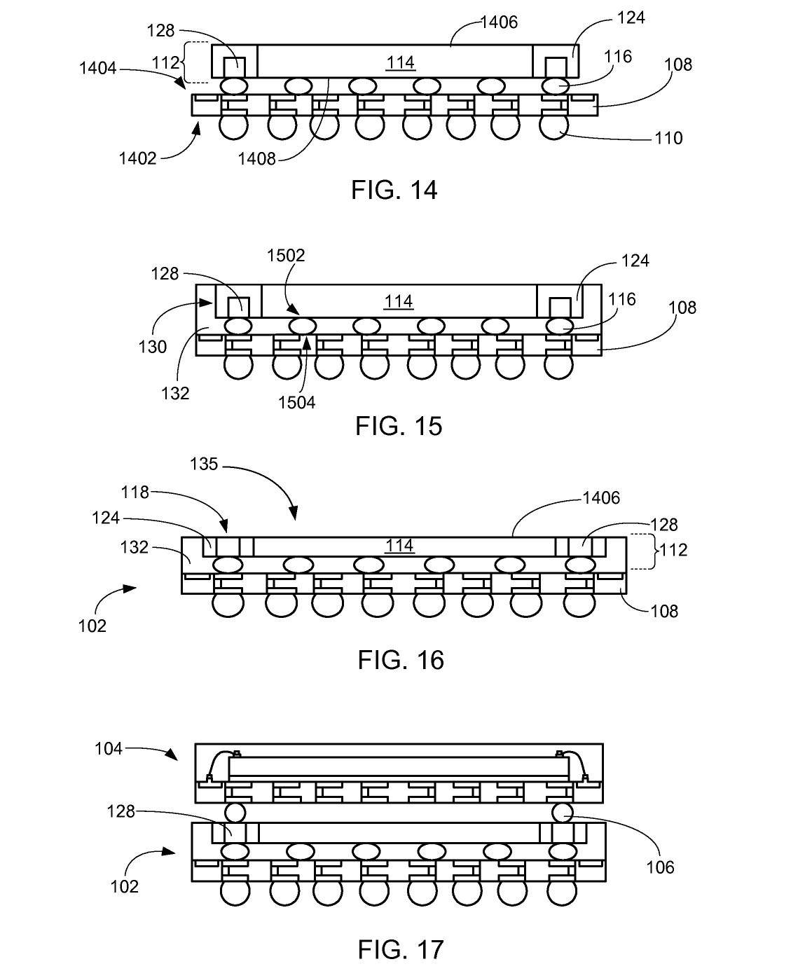

Referring now to FIG. 14, therein is shown the organic chip assembly 112 in a base substrate attach phase. The phase can include the base substrate 108, the assembly integrated circuit 114, the organic cover 124, the via conductor 128, and the assembly connector 116.

The base substrate 108 can have a bottom substrate side 1402, which is defined as a side of the base substrate 108 opposite to the side for mounting the organic chip assembly 112. The base substrate 108 can include a top substrate side 1404, which is defined as the side of the base substrate 108 opposite to the bottom substrate side 1402. The system interconnect 110 can be attached to the bottom substrate side 1402 of the base substrate 108.

The organic chip assembly 112 can be mounted to the top substrate side 1404 of the base substrate 108. The organic chip assembly 112 can include an assembly top side 1406 and an assembly bottom side 1408 below the assembly top side 1406. The assembly top side 1406 is defined as a side of the organic chip assembly 112 that is facing away from the base substrate 108. The assembly bottom side 1408 is defined as a side of the organic chip assembly 112 that is facing the base substrate 108.

Referring now to FIG. 15, therein is shown the structure of FIG. 14 in a molded underfill application phase. The phase can include the assembly integrated circuit 114, the organic cover 124, the via conductor 128, and the assembly connector 116.

The molded underfill 132 can encapsulate the top substrate side 1404 of FIG. 14, the assembly connector 116, the assembly bottom side 1408 of FIG. 14, and the vertical assembly side 130. The molded underfill 132, the organic cover 124, and the base substrate 108 provide structural rigidity for the assembly integrated circuit 114.

The assembly connector 116 can contact the assembly bottom side 1408 at a first area 1502, which is defined as the physical location of contact between the assembly connector 116 and the assembly integrated circuit 114 or the via conductor 128. The assembly connector 116 can be exposed from the molded underfill 132 at the first area 1502 between the assembly bottom side 1408 and the assembly connector 116.

The assembly connector 116 can contact the base substrate 108 at a second area 1504, which is defined as the physical location of contact between the assembly connector 116 and the base substrate 108. The assembly connector 116 can be exposed from the molded underfill 132 at the second area 1504 between the base substrate 108 and the assembly connector 116.

Referring now to FIG. 16, therein is shown the structure of FIG. 15 in an assembly top side thinning phase. The assembly top side 1406 can be thinned or back-grinded to reduce the thickness of the organic chip assembly 112 for forming the planarized assembly surface 135. The assembly top side 1406 can be back-grinded by a number of processes, such as using CMP, wheel grinding, or sawing.

The planarized assembly surface 135 can include the surfaces of the assembly integrated circuit 114, the organic cover 124, and the molded underfill 132 at the assembly top side 1406 all coplanar to each other. The assembly top side 1406 can be back-grinded until the via conductor 128 is exposed from the organic cover 124.

The base substrate 108, the organic cover 124, and the molded underfill 132 provide structural support for the assembly integrated circuit 114 during thinning or back-grinding. The base substrate 108, the organic cover 124, and the molded underfill 132 prevent the assembly integrated circuit 114 from breaking or fracturing during the thinning or back-grinding process.

The via conductor 128 exposed from the organic cover 124 forms the through via 118. The organic chip assembly 112, the molded underfill 132, and the base substrate 108 together form the organic base package 102.

It has been discovered that the base substrate 108, the organic cover 124, and the molded underfill 132 provide structural support for the assembly integrated circuit 114 during thinning or back-grinding. The base substrate 108, the organic cover 124, the molded underfill 132 provide a supporting structure for increasing the rigidity of the assembly integrated circuit 114 and thus prevent the fracture of the assembly integrated circuit 114 during a thinning or back-grinding process.

Referring now to FIG. 17, therein is shown the structure of FIG. 16 in a stacked package attachment phase. The package interconnect 106 can be mounted to the via conductor 128 at the assembly top side 1406 of FIG. 14. The stack package 104 can be mounted on top of the package interconnect 106. The stack package 104 and the organic base package 102 together form the integrated circuit packaging system 100 as shown in FIG. 1.

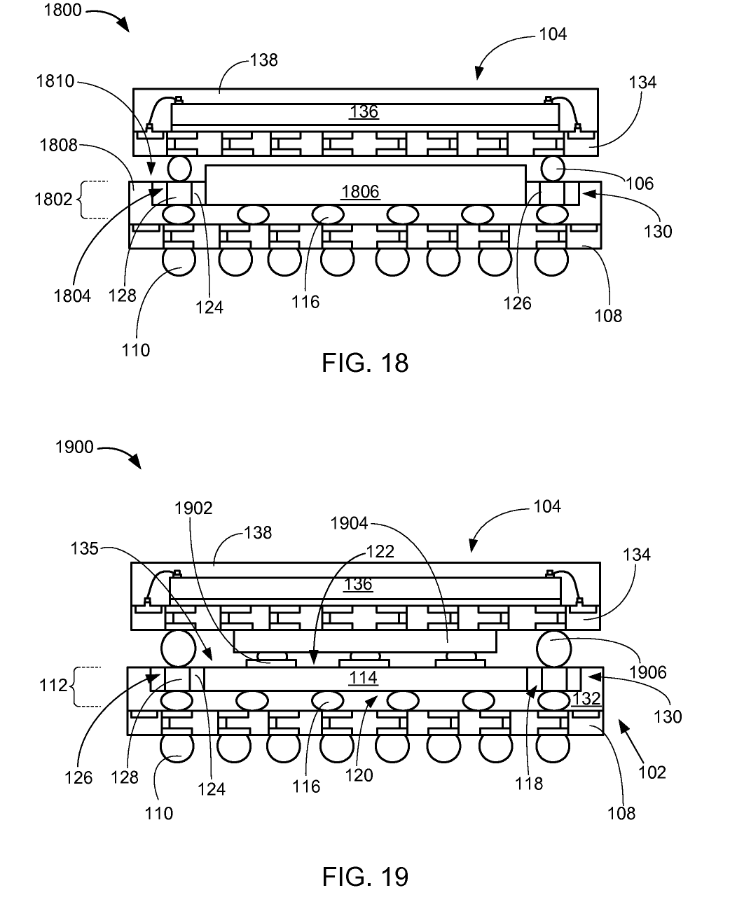

Referring now to FIG. 18, therein is shown a cross-sectional view of an integrated circuit packaging system 1800 exemplified by the top view along line 1-1 of FIG. 2 in a third embodiment of the present invention. The integrated circuit packaging system 1800 can be similar to the integrated circuit packaging system 100 of FIG. 2 except the integrated circuit packaging system 1800 includes a second organic chip assembly 1802 having a periphery region with a thickness less than the thickness of a second assembly integrated circuit 1806.

The second assembly integrated circuit 1806 is defined as a semiconductor device, which forms a non-periphery region of the second organic chip assembly 1802. The second assembly integrated circuit 1806 can be similar to the assembly integrated circuit 114 of FIG. 1.

The second organic chip assembly 1802 can include a second through via 1804. The second through via 1804 can be similar to the through via 118 of FIG. 1 except the second through via 1804 can be back-grinded or cross sawed during singulation to have the thickness less than the thickness of the second assembly integrated circuit 1806. The second through via 1804 with a thickness less than the thickness of the second assembly integrated circuit 1806 allows for reduced package size and package system profile without having to back-grind the second assembly integrated circuit 1806.

The organic cover 124 is defined as an organic polymer for enclosing the vertical sidewalls of the second assembly integrated circuit 1806. The organic cover 124 can surround the vertical sidewalls of the second assembly integrated circuit 1806 but not cover the active side and the inactive side of the second assembly integrated circuit 1806. The organic cover 124 can provide structural support during chip thinning and back-grinding of the second assembly integrated circuit 1806. The organic cover 124 can be formed from epoxy molding compound (EMC), moldable underfill (MUF), Polyimide (PI), Benzocyclobutene (BCB), or other organic resin materials.

The organic cover 124 can include the hole 126, which is defined as an opening or hole formed completely through the organic cover 124. The hole 126 can be formed away from the second assembly integrated circuit 1806 such that the vertical sides of the second assembly integrated circuit 1806 are not exposed from the organic cover 124. The hole 126 can be filled with the via conductor 128 for forming the second through via 1804.

The organic cover 124 can be back-grinded to have the thickness less than the thickness of the second assembly integrated circuit 1806 and for exposing the via conductor 128 from the organic cover 124. The molded underfill 132 of FIG. 1 can be back-grinded for forming a second molded underfill 1808 having thickness less than the thickness of the second assembly integrated circuit 1806.

The organic cover 124 and the second molded underfill 1808 can be planarized to form a planarized periphery surface 1810. The planarized periphery surface 1810 is defined as a surface of the organic cover 124 and the second molded underfill 1808 facing the stack package 104, and having the thickness less than the thickness of the second assembly integrated circuit 1806. The planarized periphery surface 1810 can be back-grinded or thinned using a wheel grinder, a saw, or CMP.

The base substrate 108 is defined as a base structure that provides support and connectivity for other components and devices. The base substrate 108 can include conductive layers and conductive traces embedded therein.

The system interconnect 110 is defined as an electrical connector providing direct electrical and mechanical to the next system level (not shown). As an example, the system interconnect 110 can be solder balls, solder pillars, or conductive bumps. The system interconnect 110 can be used to attach the base package to the next level system.

The via conductor 128 is defined as a conductive material within the hole 126 for providing an electrical pathway. For example, the conductive substance of the via conductor 128 can include solder, aluminum, copper, silver, gold, or other conductive materials.

The via conductor 128 within the hole 126 can form the second through via 1804. The second through via 1804 can provide a vertical electrical connection passing completely through the organic cover 124.

The assembly connector 116 can be mounted on the via conductor 128 of the second through via 1804 and mounted to the active side of the second assembly integrated circuit 1806. The size of the assembly connector 116 can be proportional to the width of the opening of the hole 126. The height of the assembly connector 116 and the organic cover 124 with the second through via 1804 allows for smaller solder balls to be used in the integrated circuit packaging system 100.

The assembly connector 116 can attach the second organic chip assembly 1802 to the base substrate 108. The second organic chip assembly 1802 can also include the vertical assembly side 130, which is defined as a non-horizontal side of the second organic chip assembly 1802 and perpendicular to the inactive side of the second assembly integrated circuit 1806.

The second organic chip assembly 1802 can be sealed with a second molded underfill 1808, which is defined as curable liquid underfill material for sealing integrated circuits and semiconductor structures. For example, the second molded underfill 1808 can be a material that is liquid at room temperature and curable by heat to form a solid.

The second molded underfill 1808 can provide mechanical and environmental protection for the organic base package 102. The second molded underfill 1808 can encapsulate the active side of the second assembly integrated circuit 1806, the vertical assembly side 130, the assembly connector 116, and between the second organic chip assembly 1802 and the base substrate 108 for providing mechanical and environmental protection.

The integrated circuit packaging system 100 can include the stack package 104, which is defined as an integrated circuit package for mounting above a base package. The stack package 104 can include the stack substrate 134, the stack semiconductor device 136, and the stack encapsulation 138.

The package interconnect 106 can be mounted on the second through via 1804, and the stack package 104 can be mounted on the package interconnect 106 and mounted over the inactive side of the second assembly integrated circuit 1806. The stack semiconductor device 136 is defined as an integrated circuit of the stack package 104.

For illustrative purposes, the stack semiconductor device 136 can include a wire-bond device or flip chip. The stack encapsulation 138 is defined as an encapsulation for the stack package 104. The stack encapsulation 138 can include an epoxy molding compound (EMC), polymide compound, or a wire-in-film (WIF).

It has been discovered that the organic cover 124 with the second through via 1804 of the second organic chip assembly 1802 provides the integrated circuit packaging system 100 with a finer pitch interconnect over prior art package-on-package (PoP) technology. The organic cover 124 with the through via 118 provides a conductive mounting structure for smaller solder balls and interconnects between packages. The smaller solder balls and interconnects provide for finer pitch interconnections between the stack package 104 and the organic base package than a larger solder ball for connecting the stack package 104 with a convention base package.

The width of the hole 126 and the via conductor 128 of the second through via 1804 enables the conductive material mounted thereon to be smaller in size resulting in increased IO density between the stack package 104 and the organic base package. The smaller size of the package interconnect 106 and the assembly connector 116 also prevents solder ball collapse over larger conventional solder balls during reflow.

Further, it has been discovered that the stacking configuration of the organic base package and the stack package 104 reduces the impact of the coefficient of thermal expansion and thus prevents damage to the integrated circuit packaging system 1800. The placement of the second through via 1804, the second molded underfill 1808, the assembly connector 116, the package interconnect 106, and the system interconnect 110 provide for a similar coefficient of thermal expansion at each package level of the integrated circuit packaging system 1800, preventing interconnect fractures between the organic base package and the stack package 104.

Further, it has been discovered that the organic cover 124 enclosing the vertical sidewalls of the second assembly integrated circuit 1806 and the base substrate 108 provide for structural support for the second assembly integrated circuit 1806 during thinning, back-grinding, or chemical mechanical planarization. The organic cover 124 and the base substrate 108 provide a supporting structure for the second assembly integrated circuit 1806 and the increased support prevents the second assembly integrated circuit 1806 from breaking or fracturing during die thinning.

Further, it has been discovered that the organic cover 124 with the second through via 1804 on the peripheral of the second assembly integrated circuit 1806 provides for interchangeable packages to be mounted to the organic base package 102. The configuration of the organic base package makes multiple function integration possible. The organic base package with the second molded underfill 1808 sealing the second organic chip assembly 1802, and the base substrate 108 provides for lower production line utilization by removing the need of additional steps, adhesives, separate underfill, and molds.

It has been discovered that the back-grinding of the second molded underfill 1808 and the organic cover 124 for forming the planarized periphery surface 1810 creates a lower profile for the package without having to back-grind and potentially damage the second assembly integrated circuit 1806. The planarized periphery surface 1810 with a thickness less than the thickness of the second assembly integrated circuit 1806 lowers the package profile without the need to back-grind the second assembly integrated circuit 1806.

Referring now to FIG. 19, therein is shown a cross-sectional view of an integrated circuit packaging system 1900 exemplified by the top view along line 1-1 of FIG. 2 in a fourth embodiment of the present invention. The integrated circuit packaging system 1900 can be similar to the integrated circuit packaging system 100 of FIG. 2 except a redistribution layer (RDL) 1902, an intermediate flip chip 1904, and a second package interconnect 1906 can be mounted on the organic chip assembly 112.

The RDL 1902 is defined as a conductive layer on a semiconductor device that can provide conductive paths to connections or pins at different locations on a semiconductor device. The RDL 1902 can be mounted on the inactive side 122 of the assembly integrated circuit 114.

The intermediate flip chip 1904 is defined as a flip chip semiconductor device mounted between the stack package 104 and the organic base package 102. The intermediate flip chip 1904 can be mounted on the RDL 1902. The inactive side of the intermediate flip chip 1904 can be attached to the stack substrate 134 of the stack package 104.

The second package interconnect 1906 is defined as a conductive structure for mounting the stack package 104 to the organic base package 102. The second package interconnect 1906 can include solder, solder balls, solder dots, solder bumps, or other conductive structures. The second package interconnect 1906 can be similar to the package interconnect 106 of FIG. 1 except that the second package interconnect 1906 can be larger to provide space for the intermediate flip chip 1904.

The organic base package 102 is defined as a base package, with organic structures, for providing structural support and environmental protection for an integrated circuit. The organic base package 102 can include the base substrate 108, the system interconnect 110, and the organic chip assembly 112.

The base substrate 108 is defined as a base structure that provides support and connectivity for other components and devices. The base substrate 108 can include conductive layers and conductive traces embedded therein.

The system interconnect 110 is defined as an electrical connector providing direct electrical and mechanical to the next system level (not shown). As an example, the system interconnect 110 can be solder balls, solder pillars, or conductive bumps. The system interconnect 110 can be used to attach the organic base package 102 to the next level system.

The organic chip assembly 112 is defined as an integrated circuit structure including the assembly integrated circuit 114, the assembly connector 116, and the organic cover 124 with the through via 118. The assembly integrated circuit 114 is defined as an integrated circuit of the organic chip assembly 112. The assembly integrated circuit 114 can have the active side 120 with active circuitry fabricated thereon and the inactive side 122 opposite to the active side 120.

The assembly connector 116 is defined as conductive structure for mounting the organic chip assembly 112 to another structure. As an example, the assembly connector 116 can be solder balls, solder pillars, or conductive bumps. The assembly connector 116 can be used to mount the organic chip assembly 112 to the base substrate 108.

The organic cover 124 is defined as an organic polymer for enclosing the vertical sidewalls of the assembly integrated circuit 114. The organic cover 124 can surround the vertical sidewalls of the assembly integrated circuit 114 but not cover the active side 120 and the inactive side 122 of the assembly integrated circuit 114. The organic cover 124 can provide structural support during chip thinning and back-grinding of the assembly integrated circuit 114. The organic cover 124 can be formed from epoxy molding compound (EMC), moldable underfill (MUF), Polyimide (PI), Benzocyclobutene (BCB), or other organic resin materials.

The organic cover 124 can include the hole 126, which is defined as an opening or hole formed completely through the organic cover 124. The hole 126 can be formed away from the assembly integrated circuit 114 such that the vertical sides of the assembly integrated circuit 114 are not exposed from the organic cover 124. The hole 126 can be filled with the via conductor 128 for forming the through via 118.

The via conductor 128 is defined as a conductive material within the hole 126 for providing an electrical pathway. For example, the conductive substance of the via conductor 128 can include solder, aluminum, copper, silver, gold, or other conductive materials.

The via conductor 128 within the hole 126 can form the through via 118. The through via 118 can provides a vertical electrical connection passing completely through the organic cover 124.

The assembly connector 116 can be mounted on the via conductor 128 of the through via 118 and mounted to the active side 120 of the assembly integrated circuit 114. The size of the assembly connector 116 can be proportional to the width of the opening of the hole 126. The height of the assembly connector 116 and the organic cover 124 with the through via 118 allows for smaller solder balls to be used in the integrated circuit packaging system 1900.

The assembly connector 116 can attach the organic chip assembly 112 to the base substrate 108. The organic chip assembly 112 can also include the vertical assembly side 130, which is defined as a non-horizontal side of the organic chip assembly 112 and perpendicular to the inactive side 122 of the assembly integrated circuit 114.

The organic base package 102 can include the molded underfill 132, which is defined as curable liquid underfill material for sealing integrated circuits and semiconductor structures. For example, the molded underfill 132 can be a material that is liquid at room temperature and curable by heat to form a solid.

The molded underfill 132 can provide mechanical and environmental protection for the organic base package 102. The molded underfill 132 can encapsulate the active side 120 of the assembly integrated circuit 114, the vertical assembly side 130, the assembly connector 116, and between the organic chip assembly 112 and the base substrate 108 for providing mechanical and environmental protection.

The organic base package 102 can include the planarized assembly surface 135. The planarized assembly surface 135 is defined as a planarized surface of the organic chip assembly 112 and the molded underfill 132 that faces away from the base substrate 108. The planarized assembly surface 135 can include the inactive side 122 of the assembly integrated circuit 114 and surfaces of the molded underfill 132, the organic cover 124, and the via conductor 128 that face away from the base substrate 108.

The molded underfill 132 and the organic chip assembly 112 can be thinned or back-grinded to form the planarized assembly surface 135. The planarized assembly surface 135 can be thinned or back-grinded by a number of processes including chemical mechanical planarization (CMP), wheel grinding, or sawing.

The integrated circuit packaging system 1900 can include the stack package 104, which is defined as an integrated circuit package for mounting above a base package. The stack package 104 can include the stack substrate 134, the stack semiconductor device 136, and the stack encapsulation 138.

The package interconnect 106 can be mounted on the through via 118, and the stack package 104 can be mounted on the package interconnect 106 and mounted over the inactive side 122 of the assembly integrated circuit 114. The stack semiconductor device 136 is defined as an integrated circuit of the stack package 104.

For illustrative purposes, the stack semiconductor device 136 can include a wire-bond device or flip chip. The stack encapsulation 138 is defined as an encapsulation for the stack package 104. The stack encapsulation 138 can include an epoxy molding compound (EMC), polymide compound, or a wire-in-film (WIF).

It has been discovered that the organic cover 124 with the through via 118 of the organic chip assembly 112 provides the integrated circuit packaging system 1900 with a finer pitch interconnect over prior art package-on-package (PoP) technology. The organic cover 124 with the through via 118 provides a conductive mounting structure for smaller solder balls and interconnects between packages. The smaller solder balls and interconnects provide for finer pitch interconnections between the stack package 104 and the organic base package 102 than a larger solder ball for connecting the stack package 104 with a convention base package.

The width of the hole 126 and the via conductor 128 of the through via 118 enables the conductive material mounted thereon to be smaller in size resulting in increased IO density between the stack package 104 and the organic base package 102. The smaller size of the package interconnect 106 and the assembly connector 116 also prevents solder ball collapse over larger conventional solder balls during reflow.

Further, it has been discovered that the stacking configuration of the organic base package 102 and the stack package 104 reduces the impact of the coefficient of thermal expansion and thus prevents damage to the integrated circuit packaging system 1900. The placement of the through via 118, the molded underfill 132, the assembly connector 116, the package interconnect 106, and the system interconnect 110 provide for a similar coefficient of thermal expansion at each package level of the integrated circuit packaging system 1900, preventing interconnect fractures between the organic base package 102 and the stack package 104.

Further, it has been discovered that the organic cover 124 enclosing the vertical sidewalls of the assembly integrated circuit 114 and the base substrate 108 provide for structural support for the assembly integrated circuit 114 during thinning, back-grinding, or chemical mechanical planarization. The organic cover 124 and the base substrate 108 provide a supporting structure for the organic chip assembly 112 and the increased support prevents the assembly integrated circuit 114 from breaking or fracturing during die thinning.

Further, it has been discovered that the organic cover 124 with the through via 118 on the peripheral of the assembly integrated circuit 114 provides for interchangeable packages to be mounted to the organic base package 102. The configuration of the organic base package 102 makes multiple function integration possible. The organic base package 102 with the molded underfill 132 sealing the organic chip assembly 112 to the base substrate 108 provides for lower production line utilization by removing the need of additional steps, adhesives, separate underfill, and molds.

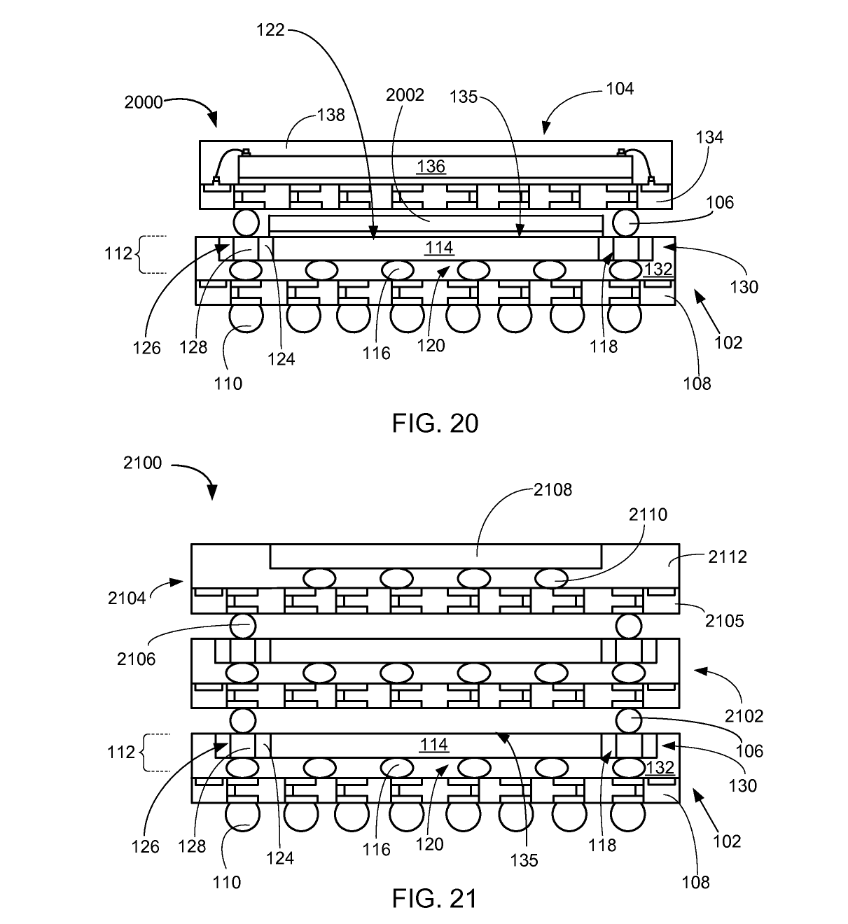

Referring now to FIG. 20, therein is shown a cross-sectional view of an integrated circuit packaging system 2000 exemplified by the top view along line 1-1 of FIG. 2 in a fifth embodiment of the present invention. The integrated circuit packaging system 2000 can be similar to the integrated circuit packaging system 100 of FIG. 2 except the integrated circuit packaging system 2000 includes a thermal heat sink 2002.

The thermal heat sink 2002 is defined as a component that transfers heat generated by a semiconductor device using convection cooling. The thermal heat sink 2002 can be mounted between the stack package 104 and the organic base package 102, and mounted on the inactive side 122 of the assembly integrated circuit 114. The thermal heat sink 2002 can provide convection cooling for the stack package 104.

The organic base package 102 is defined as a base package, with organic structures, for providing structural support and environmental protection for an integrated circuit. The organic base package 102 can include the base substrate 108, the system interconnect 110, and the organic chip assembly 112.

The base substrate 108 is defined as a base structure that provides support and connectivity for other components and devices. The base substrate 108 can include conductive layers and conductive traces embedded therein.

The system interconnect 110 is defined as an electrical connector providing direct electrical and mechanical to the next system level (not shown). As an example, the system interconnect 110 can be solder balls, solder pillars, or conductive bumps. The system interconnect 110 can be used to attach the organic base package 102 to the next level system.

The organic chip assembly 112 is defined as an integrated circuit structure including the assembly integrated circuit 114, the assembly connector 116, and the organic cover 124 with the through via 118. The assembly integrated circuit 114 is defined as an integrated circuit of the organic chip assembly 112. The assembly integrated circuit 114 can have the active side 120 with active circuitry fabricated thereon and the inactive side 122 opposite to the active side 120.

The assembly connector 116 is defined as conductive structure for mounting the organic chip assembly 112 to another structure. As an example, the assembly connector 116 can be solder balls, solder pillars, or conductive bumps. The assembly connector 116 can be used to mount the organic chip assembly 112 to the base substrate 108.

The organic cover 124 is defined as an organic polymer for enclosing the vertical sidewalls of the assembly integrated circuit 114. The organic cover 124 can surround the vertical sidewalls of the assembly integrated circuit 114 but not cover the active side 120 and the inactive side 122 of the assembly integrated circuit 114. The organic cover 124 can provide structural support during chip thinning and back-grinding of the assembly integrated circuit 114. The organic cover 124 can be formed from epoxy molding compound (EMC), moldable underfill (MUF), Polyimide (PI), Benzocyclobutene (BCB), or other organic resin materials.

The organic cover 124 can include the hole 126, which is defined as an opening or hole formed completely through the organic cover 124. The hole 126 can be formed away from the assembly integrated circuit 114 such that the vertical sides of the assembly integrated circuit 114 are not exposed from the organic cover 124. The hole 126 can be filled with the via conductor 128 for forming the through via 118.

The via conductor 128 is defined as a conductive material within the hole 126 for providing an electrical pathway. For example, the conductive substance of the via conductor 128 can include solder, aluminum, copper, silver, gold, or other conductive materials.

The via conductor 128 within the hole 126 can form the through via 118. The through via 118 can provides a vertical electrical connection passing completely through the organic cover 124.

The assembly connector 116 can be mounted on the via conductor 128 of the through via 118 and mounted to the active side 120 of the assembly integrated circuit 114. The size of the assembly connector 116 can be proportional to the width of the opening of the hole 126. The height of the assembly connector 116 and the organic cover 124 with the through via 118 allows for smaller solder balls to be used in the integrated circuit packaging system 2000.

The assembly connector 116 can attach the organic chip assembly 112 to the base substrate 108. The organic chip assembly 112 can also include the vertical assembly side 130, which is defined as a non-horizontal side of the organic chip assembly 112 and perpendicular to the inactive side 122 of the assembly integrated circuit 114.

The organic base package 102 can include the molded underfill 132, which is defined as curable liquid underfill material for sealing integrated circuits and semiconductor structures. For example, the molded underfill 132 can be a material that is liquid at room temperature and curable by heat to form a solid.

The molded underfill 132 can provide mechanical and environmental protection for the organic base package 102. The molded underfill 132 can encapsulate the active side 120 of the assembly integrated circuit 114, the vertical assembly side 130, the assembly connector 116, and between the organic chip assembly 112 and the base substrate 108 for providing mechanical and environmental protection.

The organic base package 102 can include the planarized assembly surface 135. The planarized assembly surface 135 is defined as a planarized surface of the organic chip assembly 112 and the molded underfill 132 that faces away from the base substrate 108. The planarized assembly surface 135 can include the inactive side 122 of the assembly integrated circuit 114 and surfaces of the molded underfill 132, the organic cover 124, and the via conductor 128 that face away from the base substrate 108.

The molded underfill 132 and the organic chip assembly 112 can be thinned or back-grinded to form the planarized assembly surface 135. The planarized assembly surface 135 can be thinned or back-grinded by a number of processes including chemical mechanical planarization (CMP), wheel grinding, or sawing.

The integrated circuit packaging system 2000 can include the stack package 104, which is defined as an integrated circuit package for mounting above a base package. The stack package 104 can include the stack substrate 134, the stack semiconductor device 136, and the stack encapsulation 138.

The package interconnect 106 can be mounted on the through via 118, and the stack package 104 can be mounted on the package interconnect 106 and mounted over the inactive side 122 of the assembly integrated circuit 114. The stack semiconductor device 136 is defined as an integrated circuit of the stack package 104.

For illustrative purposes, the stack semiconductor device 136 can include a wire-bond device or flip chip. The stack encapsulation 138 is defined as an encapsulation for the stack package 104. The stack encapsulation 138 can include an epoxy molding compound (EMC), polymide compound, or a wire-in-film (WIF).

It has been discovered that the organic cover 124 with the through via 118 of the organic chip assembly 112 provides the integrated circuit packaging system 2000 with a finer pitch interconnect over prior art package-on-package (PoP) technology. The organic cover 124 with the through via 118 provides a conductive mounting structure for smaller solder balls and interconnects between packages. The smaller solder balls and interconnects provide for finer pitch interconnections between the stack package 104 and the organic base package 102 than a larger solder ball for connecting the stack package 104 with a convention base package.

The width of the hole 126 and the via conductor 128 of the through via 118 enables the conductive material mounted thereon to be smaller in size resulting in increased IO density between the stack package 104 and the organic base package 102. The smaller size of the package interconnect 106 and the assembly connector 116 also prevents solder ball collapse over larger conventional solder balls during reflow.

Further, it has been discovered that the stacking configuration of the organic base package 102 and the stack package 104 reduces the impact of the coefficient of thermal expansion and thus prevents damage to the integrated circuit packaging system 2000. The placement of the through via 118, the molded underfill 132, the assembly connector 116, the package interconnect 106, and the system interconnect 110 provide for a similar coefficient of thermal expansion at each package level of the integrated circuit packaging system 2000, preventing interconnect fractures between the organic base package 102 and the stack package 104.

Further, it has been discovered that the organic cover 124 enclosing the vertical sidewalls of the assembly integrated circuit 114 and the base substrate 108 provide for structural support for the assembly integrated circuit 114 during thinning, back-grinding, or chemical mechanical planarization. The organic cover 124 and the base substrate 108 provide a supporting structure for the organic chip assembly 112 and the increased support prevents the assembly integrated circuit 114 from breaking or fracturing during die thinning

Further, it has been discovered that the organic cover 124 with the through via 118 on the peripheral of the assembly integrated circuit 114 provides for interchangeable packages to be mounted to the organic base package 102. The configuration of the organic base package 102 makes multiple function integration possible. The organic base package 102 with the molded underfill 132 sealing the organic chip assembly 112, and the base substrate 108 provides for lower production line utilization by removing the need of additional steps, adhesives, separate underfill, and molds.

Referring now to FIG. 21, therein is shown a cross-sectional view of an integrated circuit packaging system 2100 exemplified by the top view along line 1-1 of FIG. 2 in a sixth embodiment of the present invention. The integrated circuit packaging system 2100 can be similar to the integrated circuit packaging system 100 except the integrated circuit packaging system 2100 includes an intermediate organic package 2102 and a stack flip chip package 2104 mounted above the organic base package 102.

The intermediate organic package 2102 is defined as an integrated circuit package mounted above a base package and with organic components, for providing structural support. The intermediate organic package 2102 can be fabricated in a similar way to the organic base package 102. The intermediate organic package 2102 can be mounted over the organic base package 102 and mounted directly on the package interconnect 106. The intermediate organic package 2102 can include the identical structures of the organic base package 102 listed below.

The stack flip chip package 2104 is defined as an integrated circuit package mounted above the intermediate organic package 2102 for providing structural support and environmental protection for a flip chip semiconductor die. The stack flip chip package 2104 can include a flip chip substrate 2105, a stack flip chip die 2108, a flip chip connector 2110, and a flip chip encapsulation 2112.

The flip chip substrate 2105 is defined as a supporting structure for the stack flip chip die 2108. The stack flip chip die 2108 is defined as a flip chip integrated circuit on the flip chip substrate 2105. The flip chip connector 2110 is defined as a conductive material, such as solder balls or solder bumps for mounting the stack flip chip die 2108 to the flip chip substrate 2105.

The flip chip encapsulation 2112 is defined as an encapsulation for encapsulating the stack flip chip package 2104. The flip chip encapsulation 2112 can include an epoxy molding compound (EMC), polymide compound, or a wire-in-film (WIF). The stack flip chip package 2104 can be mounted direct on a third package interconnect 2106 that are mounted directly on the intermediate organic package 2102.

The organic base package 102 is defined as a base package, with organic structures, for providing structural support and environmental protection for an integrated circuit. The organic base package 102 can include the base substrate 108, the system interconnect 110, and the organic chip assembly 112.

The base substrate 108 is defined as a base structure that provides support and connectivity for other components and devices. The base substrate 108 can include conductive layers and conductive traces embedded therein.

The system interconnect 110 is defined as an electrical connector providing direct electrical and mechanical to the next system level (not shown). As an example, the system interconnect 110 can be solder balls, solder pillars, or conductive bumps. The system interconnect 110 can be used to attach the organic base package 102 to the next level system.

The organic chip assembly 112 is defined as an integrated circuit structure including the assembly integrated circuit 114, the assembly connector 116, and the organic cover 124 with the through via 118. The assembly integrated circuit 114 is defined as an integrated circuit of the organic chip assembly 112. The assembly integrated circuit 114 can have the active side 120 with active circuitry fabricated thereon and the inactive side 122 opposite to the active side 120.

The assembly connector 116 is defined as conductive structure for mounting the organic chip assembly 112 to another structure. As an example, the assembly connector 116 can be solder balls, solder pillars, or conductive bumps. The assembly connector 116 can be used to mount the organic chip assembly 112 to the base substrate 108.

The organic cover 124 is defined as an organic polymer for enclosing the vertical sidewalls of the assembly integrated circuit 114. The organic cover 124 can surround the vertical sidewalls of the assembly integrated circuit 114 but not cover the active side 120 and the inactive side 122 of the assembly integrated circuit 114. The organic cover 124 can provide structural support during chip thinning and back-grinding of the assembly integrated circuit 114. The organic cover 124 can be formed from epoxy molding compound (EMC), moldable underfill (MUF), Polyimide (PI), Benzocyclobutene (BCB), or other organic resin materials.

The organic cover 124 can include the hole 126, which is defined as an opening or hole formed completely through the organic cover 124. The hole 126 can be formed away from the assembly integrated circuit 114 such that the vertical sides of the assembly integrated circuit 114 are not exposed from the organic cover 124. The hole 126 can be filled with the via conductor 128 for forming the through via 118.

The via conductor 128 is defined as a conductive material within the hole 126 for providing an electrical pathway. For example, the conductive substance of the via conductor 128 can include solder, aluminum, copper, silver, gold, or other conductive materials.

The via conductor 128 within the hole 126 can form the through via 118. The through via 118 can provides a vertical electrical connection passing completely through the organic cover 124.

The assembly connector 116 can be mounted on the via conductor 128 of the through via 118 and mounted to the active side 120 of the assembly integrated circuit 114. The size of the assembly connector 116 can be proportional to the width of the opening of the hole 126. The height of the assembly connector 116 and the organic cover 124 with the through via 118 allows for smaller solder balls to be used in the integrated circuit packaging system 100.

The assembly connector 116 can attach the organic chip assembly 112 to the base substrate 108. The organic chip assembly 112 can also include the vertical assembly side 130, which is defined as a non-horizontal side of the organic chip assembly 112 and perpendicular to the inactive side 122 of the assembly integrated circuit 114.

The organic base package 102 can include the molded underfill 132, which is defined as curable liquid underfill material for sealing integrated circuits and semiconductor structures. For example, the molded underfill 132 can be a material that is liquid at room temperature and curable by heat to form a solid.

The molded underfill 132 can provide mechanical and environmental protection for the organic base package 102. The molded underfill 132 can encapsulate the active side 120 of the assembly integrated circuit 114, the vertical assembly side 130, the assembly connector 116, and between the organic chip assembly 112 and the base substrate 108 for providing mechanical and environmental protection.

The organic base package 102 can include the planarized assembly surface 135. The planarized assembly surface 135 is defined as a planarized surface of the organic chip assembly 112 and the molded underfill 132 that faces away from the base substrate 108. The planarized assembly surface 135 can include the inactive side 122 of the assembly integrated circuit 114 and surfaces of the molded underfill 132, the organic cover 124, and the via conductor 128 that face away from the base substrate 108.

The molded underfill 132 and the organic chip assembly 112 can be thinned or back-grinded to form the planarized assembly surface 135. The planarized assembly surface 135 can be thinned or back-grinded by a number of processes including chemical mechanical planarization (CMP), wheel grinding, or sawing.

The integrated circuit packaging system 2100 can include the stack package 104, which is defined as an integrated circuit package for mounting above a base package. The stack package 104 can include the stack substrate 134, the stack semiconductor device 136, and the stack encapsulation 138.

The package interconnect 106 can be mounted on the through via 118, and the stack package 104 can be mounted on the package interconnect 106 and mounted over the inactive side 122 of the assembly integrated circuit 114. The stack semiconductor device 136 is defined as an integrated circuit of the stack package 104.

For illustrative purposes, the stack semiconductor device 136 can include a wire-bond device or flip chip. The stack encapsulation 138 is defined as an encapsulation for the stack package 104. The stack encapsulation 138 can include an epoxy molding compound (EMC), polymide compound, or a wire-in-film (WIF).

It has been discovered that the organic cover 124 with the through via 118 of the organic chip assembly 112 provides the integrated circuit packaging system 2100 with a finer pitch interconnect over prior art package-on-package (PoP) technology. The organic cover 124 with the through via 118 provides a conductive mounting structure for smaller solder balls and interconnects between packages. The smaller solder balls and interconnects provide for finer pitch interconnections between the stack package 104 and the organic base package 102 than a larger solder ball for connecting the stack package 104 with a convention base package.

The width of the hole 126 and the via conductor 128 of the through via 118 enables the conductive material mounted thereon to be smaller in size resulting in increased IO density between the stack package 104 and the organic base package 102. The smaller size of the package interconnect 106 and the assembly connector 116 also prevents solder ball collapse over larger conventional solder balls during reflow.

Further, it has been discovered that the stacking configuration of the organic base package 102 and the stack package 104 reduces the impact of the coefficient of thermal expansion and thus prevents damage to the integrated circuit packaging system 2100. The placement of the through via 118, the molded underfill 132, the assembly connector 116, the package interconnect 106, and the system interconnect 110 provide for a similar coefficient of thermal expansion at each package level of the integrated circuit packaging system 2100, preventing interconnect fractures between the organic base package 102 and the stack package 104.

Further, it has been discovered that the organic cover 124 enclosing the vertical sidewalls of the assembly integrated circuit 114 and the base substrate 108 provide for structural support for the assembly integrated circuit 114 during thinning, back-grinding, or chemical mechanical planarization. The organic cover 124 and the base substrate 108 provide a supporting structure for the organic chip assembly 112 and the increased support prevents the assembly integrated circuit 114 from breaking or fracturing during die thinning

Further, it has been discovered that the organic cover 124 with the through via 118 on the peripheral of the assembly integrated circuit 114 provides for interchangeable packages to be mounted to the organic base package 102. The configuration of the organic base package 102 makes multiple function integration possible. The organic base package 102 with the molded underfill 132 sealing the organic chip assembly 112, and the base substrate 108 provides for lower production line utilization by removing the need of additional steps, adhesives, separate underfill, and molds.

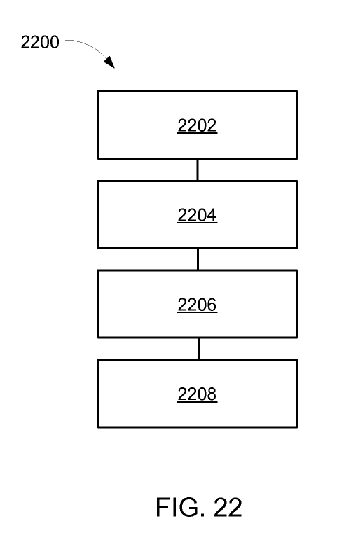

Referring now to FIG. 22 therein is shown a flow chart of a method 2200 of manufacture of the integrated circuit packaging system 100 in a further embodiment of the present invention. The method 2200 includes: providing a base substrate in a block 2202; mounting an organic chip assembly on the base substrate, the organic chip assembly includes providing an assembly integrated circuit embedded in an organic cover, the organic cover having a through via, and the organic chip assembly having a vertical assembly side in a block 2204; forming a molded underfill encapsulating the vertical assembly side, and between the organic chip assembly and the base substrate in a block 2206; and removing a portion of the organic chip assembly and the molded underfill for forming a planarized assembly surface in a block 2208.

Thus, it has been discovered that the integrated circuit packaging system of the present invention furnishes important and heretofore unknown and unavailable solutions, capabilities, and functional aspects for mold interlock. The resulting method, process, apparatus, device, product, and/or system is straightforward, cost-effective, uncomplicated, highly versatile and effective, can be surprisingly and non-obviously implemented by adapting known technologies, and are thus readily suited for efficiently and economically manufacturing integrated circuit packaging systems fully compatible with conventional manufacturing methods or processes and technologies.

Another important aspect of the present invention is that it valuably supports and services the historical trend of reducing costs, simplifying systems, and increasing performance. These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
providing a base substrate;
mounting an organic chip assembly on the base substrate, the organic chip assembly includes providing an assembly integrated circuit embedded in an organic cover, the organic cover having a through via, and the organic chip assembly having a vertical assembly side;
forming a molded underfill encapsulating the vertical assembly side, and between the organic chip assembly and the base substrate; and
removing a portion of the organic chip assembly and the molded underfill for forming a planarized assembly surface.

2. The method as claimed in claim 1 wherein removing a portion of the organic chip assembly includes removing a portion of the organic cover for exposing a via conductor from the organic cover.

3. The method as claimed in claim 1 further comprising mounting a stack package above the planarized assembly surface.

4. The method as claimed in claim 1 wherein removing the portion of the organic chip assembly includes removing a portion of the organic cover for forming a planarized periphery surface.

5. The method as claimed in claim 1 further comprising:
mounting an assembly connector between the base substrate and the organic chip assembly; and
wherein:
forming the molded underfill includes encapsulating the assembly connector with the molded underfill, the assembly connector exposed from the molded underfill at a first area between the base substrate and the assembly connector and at a second area between the organic chip assembly and the assembly connector.

6. A method of manufacture of an integrated circuit packaging system comprising:
providing a base substrate;
mounting an organic chip assembly on the base substrate, the organic chip assembly includes providing an assembly integrated circuit embedded in an organic cover, the organic cover having a through via, and the organic chip assembly having a vertical assembly side;
forming a molded underfill encapsulating a vertical assembly side, and between the organic chip assembly and the base substrate;
removing a portion of the organic chip assembly and the molded underfill for forming a planarized assembly surface; and
mounting a stack package on the planarized assembly surface and above the organic chip assembly.

7. The method as claimed in claim 6 wherein removing the portion of the organic chip assembly includes planarizing an inactive side of the organic chip assembly, the organic cover, and the molded underfill.

8. The method as claimed in claim 6 further comprising:
mounting a redistribution layer on an inactive side of the assembly integrated circuit; and
mounting an intermediate flip chip on the redistribution layer.

9. The method as claimed in claim 6 further comprising mounting a heat sink to an inactive side of the assembly integrated circuit.

10. The method as claimed in claim 6 further comprising:
mounting an intermediate organic package above the planarized surface; and
wherein:
mounting a stack package includes mounting a stack flip chip package over the intermediate organic package.

11. An integrated circuit packaging system comprising:
a base substrate;
an organic chip assembly mounted on the base substrate and having a planarized assembly surface, the planarized assembly surface includes an inactive side of an assembly integrated circuit coplanar to an organic cover with a through via, the organic chip assembly having a vertical assembly side; and
a molded underfill encapsulating the vertical assembly side, and between the organic chip assembly and the base substrate.

12. The system as claimed in claim 11 wherein the through via includes a via conductor exposed from the organic cover.

13. The system as claimed in claim 11 further comprising a stack package mounted above the planarized assembly surface.

14. The system as claimed in claim 11 wherein the organic chip assembly includes a planarized periphery surface.

15. The system as claimed in claim 11 further comprising an assembly connector mounted between the base substrate and the organic chip assembly, the assembly connector exposed from the molded underfill at a first area between the base substrate and the assembly connector and at a second area between the organic chip assembly and the assembly connector.

16. The system as claimed in claim 11 further comprising a stack package mounted above the organic chip assembly.

17. The system as claimed in claim 16 wherein the organic chip assembly includes an inactive side of the assembly integrated circuit, the organic cover, and the molded underfill all coplanar.

18. The system as claimed in claim 16 further comprising:
a redistribution layer on an inactive side of the assembly integrated circuit; and
an intermediate flip chip on the redistribution layer.

19. The system as claimed in claim 16 further comprising a heat sink mounted to an inactive side of the assembly integrated circuit.

20. The system as claimed in claim 16 further comprising:
an intermediate organic package mounted above the planarized assembly surface; and
wherein:
the stack package is a stack flip chip package mounted over the intermediate organic package.
